(19) United States
(12) Patent Application Publication
(10) Pub. No.: US 2005/0103439 A1
(43) Pub. Date: May 19, 2005

(54) Stabilization of electronegative plasmas with feedback control of RF generator systems

(75) Inventor: Daniel Goodman, Lexington, MA (US)

Correspondence Address: PROSKAUER ROSE LLP, ONE INTERNATIONAL PLACE 14TH FL, BOSTON, MA, 02110, US

(73) Assignee: Applied Science and Technology, Inc., Wilmington, MA (US)

(21) Appl. No.: 11/020,376

(22) Filed: Dec. 22, 2004

Related U.S. Application Data
(62) Division of application No. 10/151,722, filed on May 20, 2002.

(51) Int. Cl. H01L 21/306

(52) U.S. Cl. 156/345.28

(57) ABSTRACT

A method for controlling a plasma used for materials processing includes generating a power for forming an electronegative plasma, detecting a signal that is related to a parameter of the plasma, and modulating the power generated in response to the signal. Modulation of the power causes a reduction in an instability of the parameter of the plasma. An apparatus for controlling a materials processing electronegative plasma includes a signal detector for detecting a signal that is related to a parameter of the plasma, and a power modulator for causing a modulation of the power for forming the plasma in response to the signal.

### FIELD OF THE INVENTION

The present invention relates generally to plasma processing equipment. In particular, the present invention relates to stabilization of RF powered plasmas that include electronegative species.

### BACKGROUND OF THE INVENTION

Radio Frequency (RF) or microwave power supplies (hereafter “RF power supplies”) are widely used in semiconductor and industrial plasma processing equipment to generate plasmas in a process chamber. Plasma processing is used for a wide variety of applications, including etching of materials from substrates, deposition of materials on to substrates, cleaning of substrate surfaces, and modification of substrate surfaces. The frequency used for plasma processing varies widely from about 10 kHz to 2.45 GHz. The power levels used for plasma processing also vary widely, from approximately a few Watts to as much as 100 kW or greater. For semiconductor processing applications, the range of frequencies and powers presently used in plasma processing equipment is somewhat narrower, ranging from about 10 KHz to 2.45 GHz and 10 W to 30 kW, respectively.

The RF power supply can deliver power to the plasma in a number of different ways. For example, the RF power supply can be inductively coupled to the plasma via an antenna structure, capacitively coupled to the plasma, or can launch a wave that excites a resonant cavity. A conventional RF supply generally requires proper matching to the load impedance. An antenna typically has a primarily inductive load impedance, with a smaller resistive component. In contrast, a sample holder or “chuck” typically presents an impedance that is primarily capacitive, but that has a smaller resistive component. RF power is often delivered to these loads via a conventional impedance matching network.

Electronegative gasses are widely used in dry etching and other plasma processing of solid materials. An electronegative plasma is created from a recipe that includes one or more attaching gasses, such as SF₆, NF₃, CF₄ and O₂.

The behavior and stability of electronegative plasmas is generally substantially different from that of electropositive plasmas (such as an argon plasma). Instabilities peculiar to these gasses are termed “electronegative” or “electron attachment” instabilities. These instabilities can manifest themselves as large oscillations in plasma parameters.

Significant plasma parameters include, for example, electron density and temperature, ion density and temperature and plasma potential. The instabilities of these plasma parameters can be observed as fluctuations in detectable signals that are related to the parameters. Such signals include plasma current and plasma light emission.

Plasma instabilities can lead to difficulties in process control, which in turn can reduce process repeatability. Plasma instabilities are generally thought to be very difficult to control.

### SUMMARY OF THE INVENTION

Various embodiments of the invention reduce or substantially eliminate a wide range of instabilities encountered in many RF powered plasma systems. Features of the invention can provide a plasma system with increased processing reproducibility by reducing plasma fluctuations or instabilities. In various embodiments, feedback control of the amplitude of power forming an electronegative plasma, in response to a detected signal related to the plasma condition, can either eliminate or significantly reduce the size of these instabilities. In particular, some embodiments of the invention can provide stabilization of fluctuations that manifest themselves as periodic plasma parameter fluctuations exhibiting a wide range of frequencies.

Accordingly, in a first aspect, the invention features a method for controlling a plasma used for materials processing. The method includes generating a power for forming an electronegative plasma, detecting a signal that is related to a parameter of the plasma, and modulating the power generated in response to the signal. Modulating the power causes a reduction in an instability of the parameter of the plasma.

The power can be an RF power signal directed to a plasma via inductive or capacitive coupling. For example, the RF power can be directed to the plasma via a coil antenna or a substrate chuck. The parameter of the plasma can be one or more of an electron density, an ion density and a plasma potential. The detected signal can be, for example, a current, voltage or light emission. The instability can have a cyclical variation. The cyclical variation can have a frequency of greater than 0 Hz to 1 MHz or greater.

In some embodiments, the power is modulated to cause a reduction of the instability of the signal that is related to the parameter of the plasma. The signal arises from at least one of an ion current, an ion density, an electron current, an electron density, a plasma potential, and a plasma bias voltage.

In some embodiments, an RF power is increased when a plasma light emission signal or ion saturation current increases, which is counter-intuitive to generally understood principles of feedback control. Some embodiments employ a signal derived from a substrate chuck.

Modulation of the power can include variation of an amplitude of the power. The modulation of the power can include causing a cyclic variation of the amplitude of the power. The cyclic variation can have a frequency in a range of greater than 0 Hz to approximately 1 MHz or more.

In a second aspect, the invention features an apparatus for controlling electronegative plasmas that are used for materials processing. The apparatus includes a signal detector for detecting a signal that is related to a parameter of the plasma. The apparatus also includes a power modulator. The power modulator can cause a modulation of the power for forming the plasma in response to the signal. The modulation causes a reduction of an instability of the parameter of the plasma.

The power modulator can be configured for varying an amplitude of the power. The signal detector can include at least one of a current probe, a voltage probe, an optical emission detector and a workpiece holder voltage monitor. The apparatus can further include an electronegative material supply. The supply can provide the plasma with an electronegative material that includes at least one electronegative species.

### BRIEF DESCRIPTION OF THE DRAWINGS

The above and further advantages of this invention may be better understood by referring to the following description in conjunction with the accompanying drawings, in which like numerals indicate like structural elements and features in various figures. The drawings are not necessarily to scale, emphasis instead being placed upon illustrating the principles of the invention.

FIG. 1 is a block diagram of an embodiment of a plasma processing system.

FIG. 2 is a block diagram of a detailed embodiment of a plasma process system.

FIGS. 3a-3d are graphs of a detected signal (upper curve) and a control signal (lower curve) for the system illustrated in FIG. 2, operated with a SF₆-based plasma.

FIGS. 4a-4d are graphs of a control signal (upper curve), an optical emission signal (lower curve) and a detected signal (middle curve in FIGS. 4a and 4b), for the system illustrated in FIG. 2 operated with an O₂-based plasma.

FIG. 5 is a graph of a light emission signal detected by a photodiode detector (upper curve), an RF voltage measured in a matchbox (middle curve), and a modulated RF signal supplied by a power modulator (lower curve), for the system illustrated in FIG. 2 operated with a SF₆-based plasma.

FIG. 6 is a graph of a light emission signal (upper curve) detected by a photodiode detector and an ion saturation current (lower curve) detected by Langmuir probe for the system illustrated in FIG. 2, operated with an SF₆-based plasma.

### DETAILED DESCRIPTION

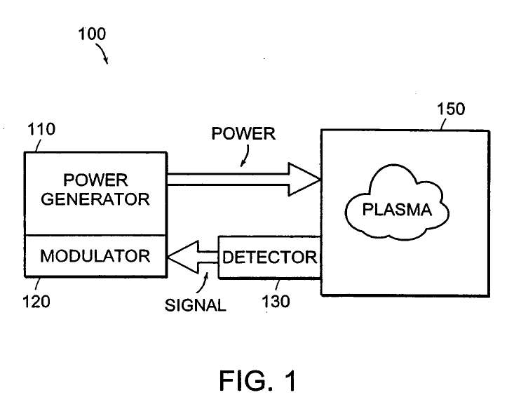

FIG. 1 is a block diagram of a plasma processing system 100, according to principles of the invention. The system 100 includes a plasma chamber 150, a power generator 110, a power modulator 120 and a signal detector 130. The power generator 110 directs power, for example, RF power, to the chamber 150 via, for example, antenna or capacitive-coupling means. The power enables formation of a plasma, such as a plasma that includes an electronegative species. The signal detector 130 can collect a signal from the plasma that is related to a parameter of the plasma, and can have a particular relationship or correlation to the parameter of the plasma. The power modulator 120 can modulate the power produced by the power generator 110, in response to the detected signal, to reduce an instability of the parameter of the plasma. The power modulator 120 can modulate the power by, for example, modulating an amplitude of an RF power produced by the power generator 110.

The plasma chamber 150 preferably contains a plasma that includes an electronegative species. Such a plasma can be formed, for example, from fluorine, oxygen and/or halogen-containing compounds such as hydrogen bromide. The parameters of one or more electronegative species in the plasma, such as ion density and temperature, can be important for processing applications that rely on aspects of the behavior of the electronegative species. Instability of the parameters can be particularly detrimental to attempts to run a consistent, predictable process. Instability of these parameters can be fluctuations that arise, for example, from the physical nature of a plasma, the design and construction of a particular plasma system, and the particular operating conditions of the plasma system.

The parameter of the plasma can include, for example, one or more of an electron density, electron temperature, negative ion density, negative ion temperature, positive ion density, and positive ion temperature. As described herein, principles of the invention permit the substantial reduction of a wide range of instabilities of one or more parameters of a plasma. The term “electronegative plasma” as used herein means a plasma formed, at least in part, from one or more electronegative materials, which can include electronegative gasses.

The signal detector 130 can include one or more of a variety of means to detect a signal that arises from the plasma and fluctuates in correlation to an instability of a parameter of the plasma. The terms “collect” and “detect” herein are used interchangeably. Collected signals can include any signal that is related to a plasma. For example, collected signals can include an electron current, an ion current, a plasma potential, a plasma bias voltage and/or a plasma light emission. Preferred embodiments collect a signal that is correlated to a positive ion density because determination of negative ion density can entail deconvolution of electron density and/or electron current effects.

Some embodiments of a system 100, include a Langmuir probe, an optical emission detector, a capacitive voltage probe (to collect, for example, a plasma potential) or a substrate chuck bias voltage monitor as the signal detector 130. Such probes or detectors are known to those having ordinary skill in the semiconductor plasma processing arts. An optical emission detector or a bias voltage monitor can have the advantage of requiring no placement of a detector within the plasma chamber 150.

The power modulator 120 is configured to utilize the signal collected from the plasma. The collected signal optionally can be processed prior to delivery to the power modulator 120. For example, RF frequencies can be removed from the detected signal, for example, via filtering, to provide a filtered control signal that correlates to an amplitude fluctuation of the originally collected signal.

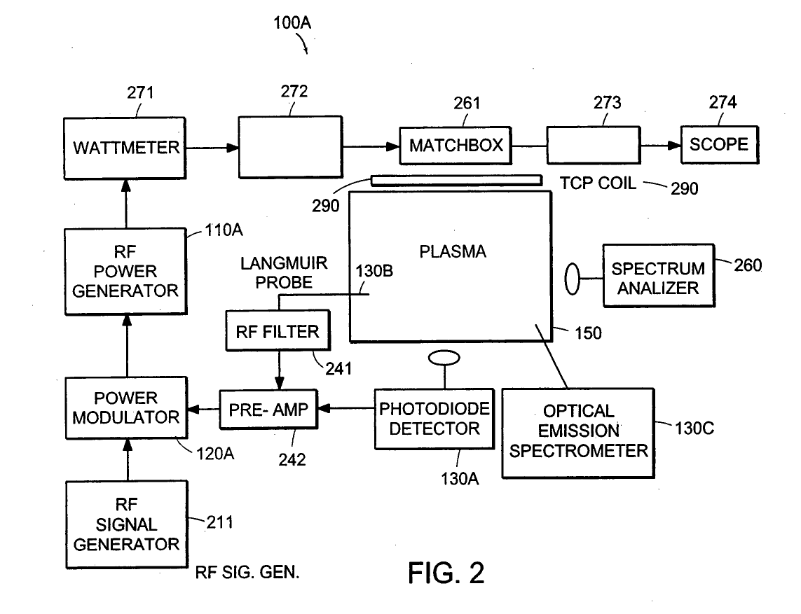

FIG. 2 is a block diagram of a detailed embodiment of a plasma processing system 100A, which was assembled and operated to illustrate the stabilization of some electronegative plasma instabilities, according to principles of the invention.

The system 100A includes a transformer-coupled plasma (TCP) coil antenna 290, an impedance matching system (or matchbox) 261, an RF signal generator 211, an RF power modulator 120A, an RF power generator 110A, a wattmeter unit 271, a plasma impedance analyzer 272, an RF current-voltage monitor 273, and an oscilloscope 274. The system 100A further includes a swept Langmuir probe 130B, an RF filter 241, and a signal preamplifier 242. The system 100A also includes a photodiode detector 130A with sub-microsecond response time, an optical spectrometer 130C (including a photomultiplier tube tuned to the flourine atomic line at 703.7 nm), and a pickup coil connected to a spectrum analyzer 260 for plasma RF spectrum measurements.

The RF power modulator 120A modulates an RF signal supplied by the RF signal generator 211 to the RF power generator 110A. The RF power generator 110A amplifies the RF signal to provide the RF power to the plasma. The power output of the generator 110A is directed at the plasma via the impedance matchbox 261 and the coil 290. The current-voltage monitor 273 permits monitoring of the current and voltage output by the matchbox 261 to the coil 290, and the oscilloscope 274 permits graphing of the RF power delivered to the coil 290.

The wattmeter unit 271 supports analysis of the antenna match via measurement of the voltage standing-wave ratio (VSWR), as known to one having ordinary skill in the RF antenna transmission arts. Antenna match can be a significant factor in the overall power utilization efficiency of a RF-based plasma processing system.

The swept Langmuir probe 130B was configured as known to one having skill in the Langmuir probe arts to detect electron temperature and density. The signal detected by the Langmuir probe 130B is filtered by the RF filter 241 to remove an RF component from the detected signal, and the filtered signal is amplified by the preamplifier 242 before being supplied to the RF power modulator 120A.

The preamplifier 242 and the RF filter 241 can, for example, be combined as a single unit, and can be included within a housing with the RF power modulator 120A and with the RF power generator 110A. The preamplifier 242 can be, for example, a non-inverting amplifier that assists stable performance of the preamplifier 242. In some embodiments, feedback provided via the RF power modulator 120A is controlled via a computer unit. For example, the computer unit can adjust the feedback gain until the instability of the detected signal is substantially minimized. Some embodiments are configured for digital control and digital signal processing.

An optical emission signal having a range of frequencies can be monitored with the photodiode detector 130A. In the present embodiment, the optical emission spectrometer 130C is configured to be specific to detecting light emission from a fluorine species in an electronegative plasma.

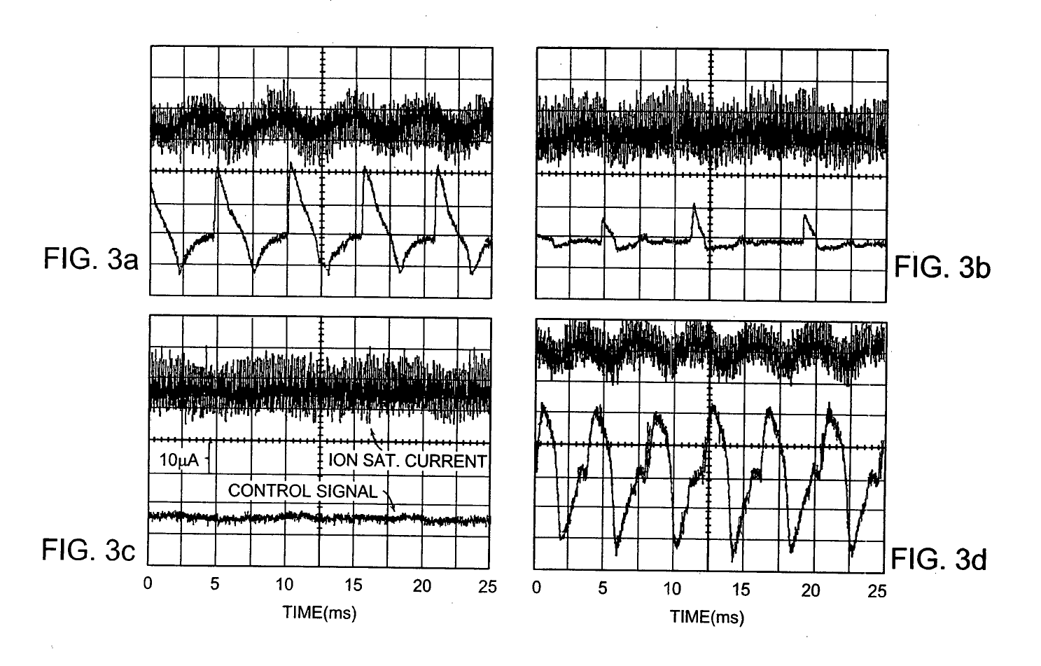

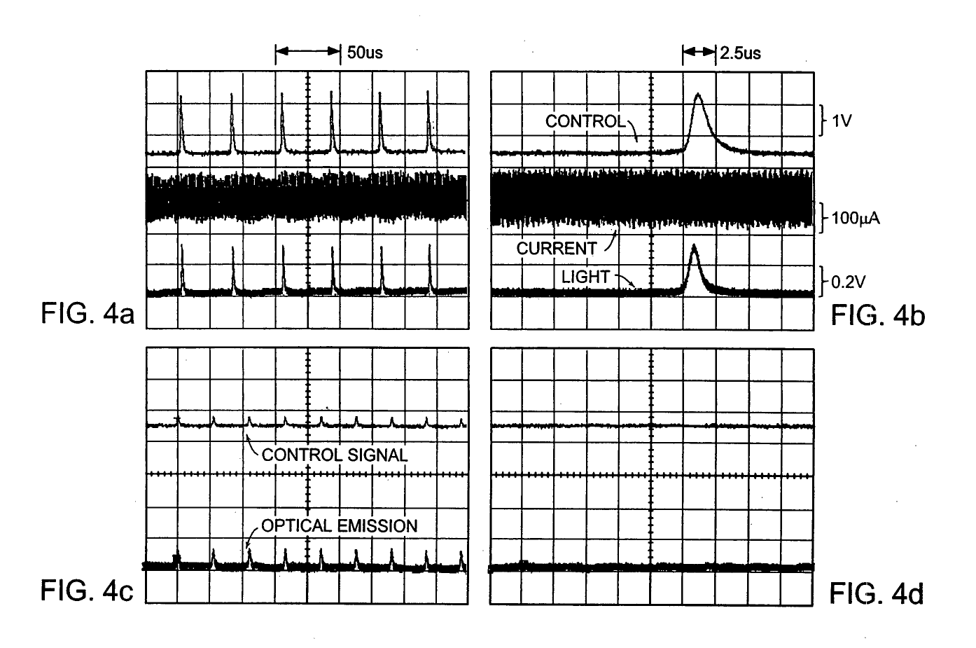

Referring to FIGS. 3 and 4, the system 100A was operated to observe some electronegative plasma instabilities, and to demonstrate stabilization of the plasma instabilities. The system 110A was operated, for example, to observe instabilities for electronegative plasmas formed from SF₆ and from O₂, with the RF generator 110A supplying RF power to the coil 290. Specific examples of some observed instabilities, and reduction of the instabilities, are described below.

FIGS. 3a-3d are graphs of the detected signal (upper curve) and a control signal (lower curve) for the system 100A, operated with an SF₆-based plasma (7.5 mTorr, 10.8 MHz, 400 W). The control signal is the filtered detected signal. The filtering, by the RF filter 241, substantially removes the high frequency (i.e., RF) component of the detected signal. The detected signal here is an ion saturation current as detected with the Langmuir probe 130B operated with a bias voltage of—64 V.

FIG. 3a illustrates one observed instability in the detected signal, which is herein referred to as an “O-mode” instability, in light of its oscillatory behavior, with an oscillatory frequency of approximately 200 Hz. The frequency of the O-mode instability was observed to vary in a range of approximately 100 Hz to 1000 Hz by changing the operating conditions.

FIGS. 3b, 3c and 3d illustrate control of the instability of the parameter of the plasma, as demonstrated through the instability evinced by the detected signal. Each of these three graphs was obtained with a different amount of modulation of the power in response to the control signal. The control signal provided a feedback signal for a corresponding modulation, by the power modulator 120A, of the power output from the power generator 110A.

FIG. 3b illustrates a moderate reduction of the instability of the detected signal with an intermediate level of feedback gain applied by the power modulator 120A. The curves for the detected signal (upper curve of the ion saturation current) and the control signal (lower curve of the filtered ion saturation current) show a decrease in the amplitude of the instability (i.e., a decrease in the peak-to-peak amplitude of the oscillations of the control signal). In this example, feedback was supplied to cause an increase in the RF amplitude in phase with an increase in the ion saturation current amplitude.

FIG. 3c illustrates substantial elimination of the instability of the detected signal via application of a greater level of feedback gain than the level employed to produce the degree of stabilization that is illustrated in FIG. 3b. The curves for the detected signal and the control signal show a substantial elimination of the O-mode instability, and thus indirectly demonstrate a substantial elimination of a corresponding instability of the electronegative plasma. The level of feedback gain was adjusted until the fluctuations in the control signal were substantially minimized.

FIG. 3d illustrates the production of an intentionally increased magnitude of the O-mode instability. The phase of the feedback here was reversed relative to that illustrated in FIGS. 3b and 3c, to provide positive feedback. The positive feedback increased the magnitude of the fluctuations of the detected signal in comparison to that observed with no feedback, as shown in FIG. 3a.

Referring to FIGS. 4a-4d, the system 100A was operated with an oxygen-based plasma. FIGS. 4a-4d are graphs of the detected signal (middle curve, only in FIGS. 4a and 4b), the control signal (upper curve, i.e., the filtered detected signal) and an optical emission signal (lower curve) as detected by the photodiode detector 130A. An oxygen-based plasma was operated at 6 mTorr, 270 W and 10.8 MHz. The detected signal was an ion saturation current detected with the Langmuir probe 130B operated with a bias voltage of −64 V.

Under the operating conditions illustrated by FIGS. 4a-4d, the system 100A exhibited an instability that is herein referred to as a “B-mode” instability due to the relatively narrow (in time) amplitude bursts of the light emission signal, appearing as brief spikes having a width of approximately 1 microsecond. The bursts occurred at a relatively high frequency, approximately 20 KHz. The time spacing of the bursts was variable from approximately 25 microseconds to approximately 100 microseconds. The spike frequency could be varied, for example, by changing the gas pressure and/or RF power.

FIG. 4a illustrates the observed B-mode instability, with no modulation of the power supplied by the RF power generator 110A. FIG. 4b corresponds to FIG. 4a, with the time scale expanded to better illustrate the shape of a light emission spike.

FIG. 4c illustrates a moderate reduction in the B-mode instability of the detected signal, obtained via modulation of the power supplied by the RF power generator 110A due to feedback applied via the power modulator 120A. The curves for the control signal (the filtered light emission signal) and the detected light emission signal show a decrease in the amplitude of the instability, that is, a decrease in the peak height of the bursts. In this example, feedback was supplied to cause an increase in the RF amplitude in phase with the light emission amplitude spikes.

FIG. 4d illustrates substantial elimination of the instability of the detected signal and control signals via application of a greater degree of feedback than the degree employed to produce FIG. 4c. The curves for the detected signal and the control signal show a substantial elimination of the B-mode instability, and thus indirectly demonstrate a substantial elimination of a corresponding instability of the electronegative plasma. The level of feedback gain was adjusted until the fluctuations in the light emission signal were substantially minimized.

Some instabilities that result in brief spiking of a detected signal can be less detrimental to plasma system performance than instabilities that exhibit a greater duration or more gradual variation. For example, the observed B-mode instability, described above, can be dominated by fluctuations in an electron density, with an ion density unable to respond significantly to a brief spike in the electron density. If a density of an electronegative ion species remains relatively stable during a rapid fluctuation of the electron density, processing can remain relatively stable.

For the example operating conditions illustrated in FIG. 4, an optical emission signal was detected with the photodiode detector 130A. A photodiode detector, in general, can provide a full spectrum analysis of emitted light. Alternatively, a narrow frequency band of the plasma light emission can be detected, for example with the optical emission spectrometer 130C configured to detect a particular frequency signal. Detection of the signal emitted by a single atomic species, e.g. fluorine, can provide a signal and filtered control signal for use in various embodiments of the invention.

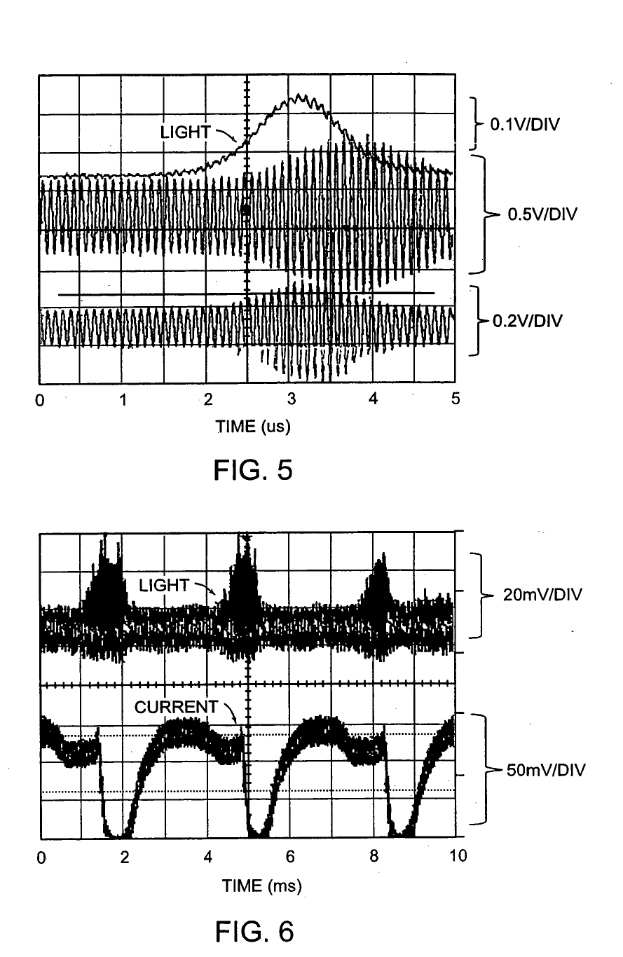

Referring to FIG. 5, a more detailed example of stabilization of a plasma parameter for the system 100A is described. FIG. 5 is a graph of a light emission and RF behavior at different locations within the system 100A when operated with a SF₆-based plasma at 12 mTorr, 700 W and 10.7 MHz. The graph shows a light emission signal detected by the photodiode detector 130A (upper curve), an RF voltage measured via a capacitive divider in the matchbox 261 (middle curve), and a modulated RF signal (lower curve) supplied by the power modulator 120A to the RF power generator 110A.

In this example, the phase of the power delivered to the coil 261 lags slightly behind the phase of the detected light emission signal. The delay is related to a time lag of approximately 2.0 microseconds between an amplitude maximum of the light emission signal and a maximum amplitude of the RF power at the matchbox 261. Approximately 0.5 microseconds of the delay arises in the preamplifier 242.

Referring to FIG. 6, a wide range of instability behaviors can be observed in a plasma processing system 100. For example, the sample processing system 100A under some operating conditions can exhibit both B-mode and O-mode instabilities. FIG. 6 is a graph of a light emission signal (upper curve) that was detected by the photodiode detector 130A for the system 100A operated with a SF₆-based plasma at 7.5 mTorr, 320 W and 10.8 MHz. FIG. 6 also shows an ion saturation current (lower curve) that was detected by the Langmuir probe 130B for the system that was operated under the same conditions.

The minima in the ion saturation current signal correspond to minima in a negative ion density parameter of the plasma. The onset of the drop in ion density corresponds to the occurrence of a burst in the light emission signal. The periodicity of the instability is comparable to that of the O-mode behavior described above, while the rapid change in ion density and light emission signal is comparable to the B-mode behavior described above.

Other embodiments of a plasma processing system 100 utilize a signal detected by means other than those described with reference to FIGS. 4 and 5. For example, a floating potential signal can be detected from a sample chuck (i.e., a “bias” as known to those having ordinary skill in the semiconductor plasma processing arts). Utilizing a signal detected via the chuck has an advantage of not requiring contact with the plasma. Detectors that contact the plasma can, for example, contaminate the plasma. Detecting a signal via the chuck has a further advantage of permitting use of many existing plasma processing chambers with modification of the chamber.

The above-described embodiments are intended to be illustrative rather than limiting. For example, features of the invention can be applied to stabilization of plasmas that do not include an electronegative species. Also, for example, features of the invention can be applied to plasma processing systems that do not require a conventional matching network. For example, some embodiments of a system that does not require a conventional matching network are described in commonly owned U.S. Pat. No. 6,150,628 to Smith et al., entitled “Toroidal Low-Field Reactive Gas Source”.

Equivalents

While the invention has been particularly shown and described with reference to specific preferred embodiments, it should be understood by those skilled in the art that various changes in form and detail may be made therein without departing from the spirit and scope of the invention as defined by the appended claims.

1. A method for controlling a plasma used for materials processing, the method comprising:
generating a power for forming a plasma comprising at least one electronegative species;
detecting a signal that is related to a parameter of the plasma comprising the electronegative species; and
modulating the power generated in response to the signal that is related to the parameter of the plasma, the modulating causing a reduction in an instability of the parameter of the plasma.

2. The method for controlling a plasma of claim 1, wherein the instability comprises a cyclical variation of the parameter.

3. The method for controlling a plasma of claim 1, wherein the instability comprises a fluctuation of a density of ions in the plasma.

4. The method for controlling a plasma of claim 1, further comprising providing the plasma comprising the electronegative species.

5. The method for controlling a plasma of claim 1, wherein the modulating the power causes a reduction of the instability of the signal that is related to the parameter.

6. The method for controlling a plasma of claim 1, wherein the signal is selected from the group consisting of a voltage signal, a current signal and an optical emission signal.

7. The method for controlling a plasma of claim 6, wherein the signal is generated from at one of an ion current, an ion density, an electron current, an electron density, a plasma potential, and a plasma bias voltage.

8. The method for controlling a plasma of claim 1, wherein the modulating the power comprises causing an amplitude variation of the power.

9. The method for controlling a plasma of claim 8, wherein the modulating the power comprises causing the amplitude variation of the power to have an in-phase relationship with an amplitude variation of the signal that is related to the parameter.

10. The method for controlling a plasma of claim 8, wherein the modulating the power comprises causing a cyclic variation of the amplitude of the power, wherein the cyclic variation comprises a frequency in a range of greater than 0 Hz to approximately 1 MHz.

11. The method for controlling a plasma of claim 10, wherein the frequency is in a range of 100 Hz to 100 KHz.

12. The method for controlling a plasma of claim 1, wherein the signal that is related to the parameter is generated by an optical emission, and wherein the modulating comprises increasing an amplitude of the power in-phase with an amplitude of the signal that is related to the parameter.

13. The method for controlling a plasma of claim 1, wherein the signal has an amplitude variation comprising a frequency that is in a range of approximately 100 Hz to approximately 100 KHz, and wherein the modulating the power comprises causing a variation of an amplitude of the power.

14. The method for controlling a plasma of claim 1, wherein the power comprises an oscillatory signal, and the modulating the power comprises causing a variation of an amplitude of the oscillatory signal.

15. The method for controlling a plasma of claim 14, wherein the oscillatory signal comprises a radio frequency signal.

16-25. (canceled)
